(19) United States
(12) Patent Application Publication
(10) Pub. No.: US 2026/0280505 A1
(43) Pub. Date: Sep. 17, 2026

(54) PLANAR SOLID STATE POWER AMPLIFIER ARCHITECTURE WITH INTEGRATED WAVEGUIDE TRANSITIONS, HEAT SINK AND COMBINER

(71) Applicant: Qorvo US, Inc., Greensboro, NC (US)

(72) Inventor: Michael Dean Roberg, Evergreen, CO (US)

(21) Appl. No.: 19/545,588

(22) Filed: Feb. 20, 2026

Related U.S. Application Data
(60) Provisional application No. 63/804,816, filed on May 13, 2025.
(60) Provisional application No. 63/772,858, filed on Mar. 17, 2025.

(51) Int. Cl. H03F 3/60; H01P 5/16; H03F 3/24

(52) U.S. Cl. CPC H03F 3/602; H01P 5/16; H03F 3/245; H03F 2200/451

(57) ABSTRACT

A device for amplifying radio frequency signals includes a planar dielectric substrate, which includes a metallized top side, metallized bottom side, a first hollow conductive slot forming an input substrate waveguide between the metallized top side and the metallized bottom side, a first substrate-integrated waveguide (SIW) forming an N-way splitter located after the first conductive slot, N power amplifiers located after the splitter, a second SIW located after the N power amplifiers and forming an N-way combiner, and a second hollow conductive slot located after the combiner and forming an output substrate waveguide between the metallized top side and the metallized bottom side. The device also includes a metallic heat sink which includes an input socket, a heat sink input waveguide aligned with the input socket and the input substrate waveguide, an output socket, and a heat sink output waveguide aligned with the output socket and the output substrate waveguide.

### CROSS REFERENCE TO RELATED APPLICATIONS

This application claims the priority benefit under 35 U.S.C. §119(e) of U.S. Provisional Patent Application No. 63/772,858 filed 17 March 2025, and Provisional Patent Application No. 63/804,816 filed 13 May 2025, each of which is hereby incorporated by reference in its entirety as though fully set forth herein.

### TECHNICAL FIELD

The subject matter described herein relates to devises, systems, and methods for radio frequency power amplification.

### BACKGROUND

The maximum output power of solid-state monolithic power amplifiers may be limited by the power density of the technology as well as the largest monolithic die that can be effectively designed and fabricated. The achievable output power degrades as a function of frequency for many reasons, inevitably leading to the desire to combine multiple monolithic or packaged dies within a single module, often referred to as a Solid-State Power Amplifier (SSPA). SSPAs are especially desirable at millimeter wave frequencies, where the output power of an individual Monolithic Microwave Integrated Circuit (MMIC) is often limited to a few Watts. High orders of combining have been demonstrated in traditional waveguide technology by using radial combiners and other methods based on rectangular waveguides. However, these approaches can be quite large from a size and weight perspective and may also be quite costly due to the tolerance and complexity of radial waveguide combiners. A planar implementation is desirable due to its profile and cost, with substrate integrated waveguides (SIWs) being a highly effective technology for implementing power combining and splitting. However, higher orders of combining can suffer from a large size, particularly due to the need to integrate with standard external waveguide adapter sizes (e.g. the WR-10 waveguide flange diameter is 0.75 inches = ~19mm). Based on these large standard waveguide adapters, it may be quite difficult to achieve higher orders of combining, because much of the available substrate area is taken up with accepting the flanged transitions of the external waveguides used for RF input and output from the SSPA device.

### SUMMARY

Disclosed is a SIW-based SSPA with external waveguide connections machined into the heat sink. This novel SSPA has particular, but not exclusive, utility for power amplification of RF signals in the microwave range (e.g., 1 GHz to 100 GHz).

The present disclosure removes the need to use any of the planar substrate topside area for accepting the flange of the standard external waveguide component. This is accomplished by positioning the planar SIW/SSPA substrate onto a heat sink, and integrating the standard waveguide component transition socket into the heat sink rather than into the substrate itself. Rather than being placed on the topside, a slot-coupled waveguide transition is placed on the back side of the SIW where it attaches to the heat sink. This transition mates with a standard rectangular waveguide machined within the heat sink. On the back side of the heat sink is a socket where a flanged external waveguide component (bend, straight line, etc.) can be accepted without being limited by the size of the planar SIW/SSPA substrate on the top side). This greatly reduces the required size of the planar SIW/SSPA substrate. The concept can also be extended to combine two planar SSPAs within the heat sink by dividing the heat sink into two halves, and incorporating a half T-slitter into each half. This approach allows realization of a SSPA with very compact size and weight.

The approach described above allows smaller form factor and weight for a SSPA. It also maximizes the level of combining that can be done with a planar SSPA by eliminating topside real estate usage for accepting standard waveguide flanged components, placing these instead on the heat sink. This approach also reduces the cost of planar SSPA, since a smaller form factor can be achieved, and allows the potential for integration into, for example, the skin of an aircraft. It also provides a straightforward way to combine two planar SSPAs for higher power.

The novel planar SSPA device has particular but not exclusive utility for amplifying RF signals in the microwave region. One general aspect includes a device for amplifying radio frequency (RF) signals. The device includes a planar dielectric substrate that may include: a metallized top side, a metallized bottom side, a first hollow conductive slot forming an input substrate waveguide between the metallized top side and the metallized bottom side, a first substrate-integrated waveguide (SIW) forming an N-way splitter located after the first conductive slot, N power amplifiers located after the splitter, a second SIW located after the n power amplifiers and forming an N-way combiner, and a second hollow conductive slot located after the N-way combiner and forming an output substrate waveguide between the metallized top side and the metallized bottom side. The device also includes a metallic heat sink that may include: an input socket, a heat sink input waveguide aligned with the input socket and the input substrate waveguide, an output socket, and a heat sink output waveguide aligned with the output socket and the output substrate waveguide.

Implementations may include one or more of the following features. In some embodiments, the device may include: an input external waveguide affixed to the input socket and aligned with the heat sink input waveguide, and an output external waveguide affixed to the output socket and aligned with the heat sink output waveguide. In some embodiments, the input socket or the output socket is located on a bottom face of the heat sink, such that the input external waveguide or the output external waveguide extends in a direction perpendicular to the planar dielectric substrate. In some embodiments, the input socket or the output socket is located on a side face of the heat sink, such that the input external waveguide or the output external waveguide extends in a direction parallel to the planar dielectric substrate. In some embodiments, the planar dielectric substrate may include glass. In some embodiments, at least one of the heat sink input waveguide, the input substrate waveguide, the first SIW, the second SIW, the output substrate waveguide, or the heat sink output waveguide may include air. In some embodiments, the N power amplifiers may include N microwave monolithic integrated circuits (MMICs).

One general aspect includes a method for amplifying a radio frequency (RF) signal. The method includes providing a planar dielectric substrate that may include a metallized top side and a metallized bottom side. The method also includes, with a first hollow conductive slot, forming an input substrate waveguide between the metallized top side and the metallized bottom side. The method also includes, with a first substrate-integrated waveguide (SIW), forming an N-way splitter located after the first conductive slot. The method also includes providing N power amplifiers located after the splitter. The method also includes, with a second SIW located after the N power amplifiers, forming an N-way combiner. The method also includes, with a second hollow conductive slot located after the N-way combiner, forming an output substrate waveguide between the metallized top side and the metallized bottom side. The method also includes providing a metallic heat sink that may include: an input socket, a heat sink input waveguide aligned with the input socket and the input substrate waveguide, an output socket, a heat sink output waveguide aligned with the output socket and the output substrate waveguide, receiving the RF signal via the input socket, heat sink input waveguide, and the input substrate waveguide; amplifying the RF signal using the N-way splitter, the N power amplifiers, and the N-way combiner to generate an amplified RF signal; and transmitting the amplified RF signal through the output substrate waveguide, heat sink output waveguide, and output socket.

Implementations may include one or more of the following features. In some embodiments, the method may include: affixing an input external waveguide affixed to the input socket such that the input external waveguide is aligned with the heat sink input waveguide, and affixing an output external waveguide affixed to the output socket such that the output external waveguide is aligned with the heat sink output waveguide. In some embodiments, the input socket or the output socket is located on a bottom face of the heat sink, such that the input external waveguide or the output external waveguide extends in a direction perpendicular to the planar dielectric substrate. In some embodiments, the input socket or the output socket is located on a side face of the heat sink, such that the input external waveguide or the output external waveguide extends in a direction parallel to the planar dielectric substrate. In some embodiments, the N power amplifiers may include N microwave monolithic integrated circuits (MMICs). In some embodiments, the planar dielectric substrate may include glass. In some embodiments, at least one of the heat sink input waveguide, the input substrate waveguide, the first SIW, the second SIW, the output substrate waveguide, or the heat sink output waveguide may include air.

One general aspect includes a wireless device which includes an amplification device which may include: a planar dielectric substrate that may include: a metallized top side, a metallized bottom side, a first hollow conductive slot forming an input substrate waveguide between the metallized top side and the metallized bottom side, a first substrate-integrated waveguide (SIW) forming an N-way splitter located after the first conductive slot, N power amplifiers located after the splitter, a second SIW located after the N power amplifiers and forming an N-way combiner, and a second hollow conductive slot located after the N-way combiner and forming an output substrate waveguide between the metallized top side and the metallized bottom side. The device also includes a metallic heat sink that may include: an input socket, a heat sink input waveguide aligned with the input socket and the input substrate waveguide, an output socket, and a heat sink output waveguide aligned with the output socket and the output substrate waveguide.

Implementations may include one or more of the following features. In some embodiments, the wireless device may include an input external waveguide affixed to the input socket and aligned with the heat sink input waveguide, and an output external waveguide affixed to the output socket and aligned with the heat sink output waveguide. In some embodiments, the input socket or the output socket is located on a bottom face of the heat sink, such that the input external waveguide or the output external waveguide extends in a direction perpendicular to the planar dielectric substrate. In some embodiments, the input socket or the output socket is located on a side face of the heat sink, such that the input external waveguide or the output external waveguide extends in a direction parallel to the planar dielectric substrate. In some embodiments, the planar dielectric substrate may include glass. In some embodiments, at least one of the heat sink input waveguide, the input substrate waveguide, the first SIW, the second SIW, the output substrate waveguide, or the heat sink output waveguide may include air.

This Summary is provided to introduce a selection of concepts in a simplified form that are further described below in the Detailed Description. This Summary is not intended to identify key features or essential features of the claimed subject matter, nor is it intended to limit the scope of the claimed subject matter. A more extensive presentation of features, details, utilities, and advantages of the SSPA, as defined in the claims, is provided in the following written description of various embodiments of the disclosure and illustrated in the accompanying drawings.

### BRIEF DESCRIPTION OF THE DRAWINGS

Illustrative embodiments of the present disclosure will be described with reference to the accompanying drawings, of which:

FIG. 1 is a side cross-sectional view of at least a portion of an example novel planar solid-state power amplifier (SSPA), in accordance with at least one embodiment of the present disclosure.

FIG. 2 is a side cross-sectional view of a planar SSPA device, in accordance with at least one embodiment of the present disclosure.

FIG. 3 is a top view of an example planar SSPA device, in accordance with at least one embodiment of the present disclosure.

FIG. 4 is a top side perspective view of an example planar SSPA device, in accordance with at least one embodiment of the present disclosure.

FIG. 5 is a bottom side perspective view of an example planar SSPA device, in accordance with at least one embodiment of the present disclosure.

FIG. 6 is a top side perspective view of an example planar SSPA device, in accordance with at least one embodiment of the present disclosure.

FIG. 7 is a top side perspective view of an example planar SSPA device, in accordance with at least one embodiment of the present disclosure.

FIG. 8 is a top side perspective view of the planar SSPA device of FIG. 6, with the RF input waveguide and RF output waveguide attached, in accordance with at least one embodiment of the present disclosure.

FIG. 9 is a schematic, diagrammatic view of an electronic device or a wireless device comprising a novel planar SSPA device, in accordance with at least one embodiment of the present disclosure.

FIG. 10 is a schematic, diagrammatic representation, in flow diagram form, of an example signal amplification method 1000, in accordance with at least one embodiment of the present disclosure.

### DETAILED DESCRIPTION

An air-filled waveguide may be machined into a metallic heat sink or heat spreader, and operatively connected to an air-filled substrate-integrated waveguide (SIW) in the planar SSPA substrate (e.g., a glass wafer), as well as to an external waveguide component. The present disclosure uses a planar SIW/SSPA etched or formed into a metallized glass substrate, with the top side metallization connected to the back-side metallization via a metallized through-hole or backside slot. The glass substrate is then bonded to the metallic heat spreader such that the backside slot aligns with the air-filled waveguide of the heat sink. A flanged external waveguide (e.g., a WR-10 waveguide) is then bolted to the heat sink, such that it aligns with the air-filled waveguide machined into the heat sink. The external waveguide then forms a continuous RF conduit into the planar SIW/SSPA, thus allowing the external waveguide to be attached to the bottom or side of the heat sink, without sacrificing scarce, valuable area on the front or top side of the SSPA wafer itself.

The present disclosure aids substantially in shrinking the size of SSPA devices, by allowing all of the topside area of the glass SSPA wafer to be dedicated to SIWs, MMICs, redistribution layers (RDLs), and supporting electronics, with no area needed for an external waveguide socket or attachment. Implemented on a dielectric (e.g., glass) wafer bonded to a metallic heat spreader, the novel SSPA disclosed herein provides practical reduction in the size of the SSPA substrate, and thus of the overall SSPA device. This streamlined approach transforms a SSPA substrate into a fully functional SSPA device, without the normally routine need to attach external waveguides to the glass SSPA substrate itself. This unconventional approach improves the functioning of the SSPA, by allowing more power amplifier chips (e.g., MMIC chips) on the surface of the SSPA substrate and/or allowing for two SSPA substrates to be integrated onto a single heat sink, thus increasing total power throughput for the device.

These descriptions are provided for exemplary purposes only, and should not be considered to limit the scope of the novel SSPA. Certain features may be added, removed, or modified without departing from the spirit of the claimed subject matter.

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

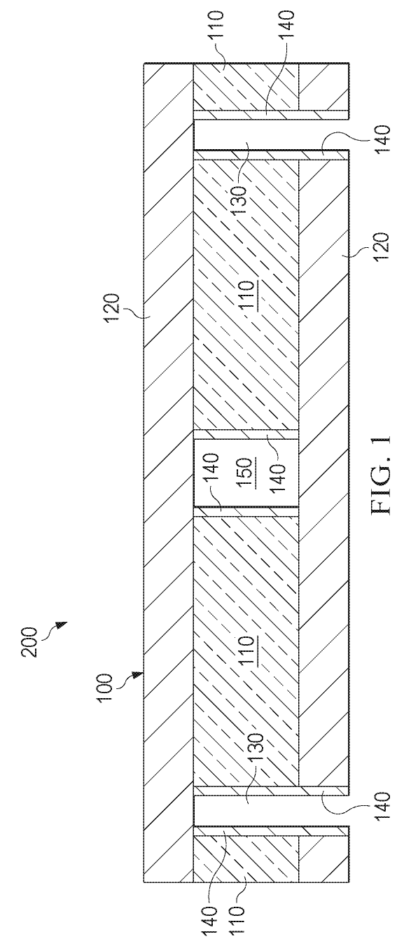

FIG. 1 is a side cross-sectional view of at least a portion of an example novel planar SSPA 100, in accordance with at least one embodiment of the present disclosure. The planar SSPA 100 includes a glass substrate 110 with top and bottom metallization layers 120 (not to scale). The glass substrate 110 and bottom metallization layer 120 include two through-holes or backside slots 130 on opposite sides of the glass substrate 110. The sides of the through-holes or backside slots 130 are coated with a metal layer 140, which may be of the same material or a different material than the metallization layers 120, thus creating pathways for electrical continuity between the top or front side metallization and the bottom or backside metallization. The glass substrate 110 also includes a void whose sides are coated with a metal layer 140, thus forming an air-filled waveguide or substrate-integrated waveguide (SIW) 150. In some implementations, the SIW 150 may connect directly with one or more backside slots 130.

These descriptions are provided for exemplary purposes only, and should not be considered to limit the scope of the novel SSPA. Certain features may be added, removed, or modified without departing from the spirit of the claimed subject matter.

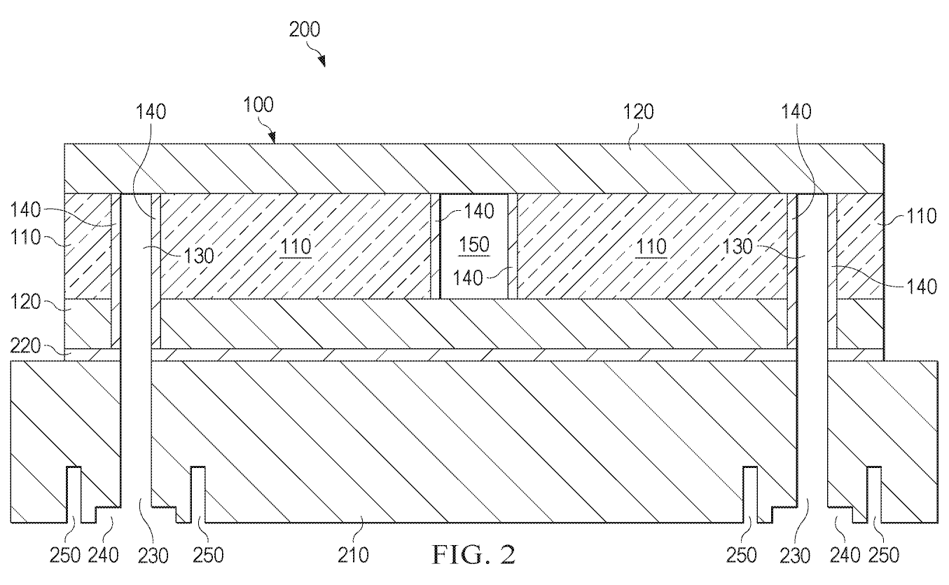

FIG. 2 is a side cross-sectional view of a planar SSPA device 200, in accordance with at least one embodiment of the present disclosure. The planar SSPA device 200 includes the planar SSPA 100 of FIG. 1, bonded to a heat sink or heat spreader 210 by a bond line 220 (e.g., a thin layer of solder or conductive epoxy). The heat sink or heat spreader 210 includes two machined, air-filled waveguides 230 that align with the backside slots 130 of the planar SSPA 100, thus forming a continuous waveguide structure. Each waveguide 230 terminates in a socket 240 for receiving an external waveguide adapter. Each socket 240 includes bolt holes 250 for bolting the external waveguide adapter to the heat sink 210.

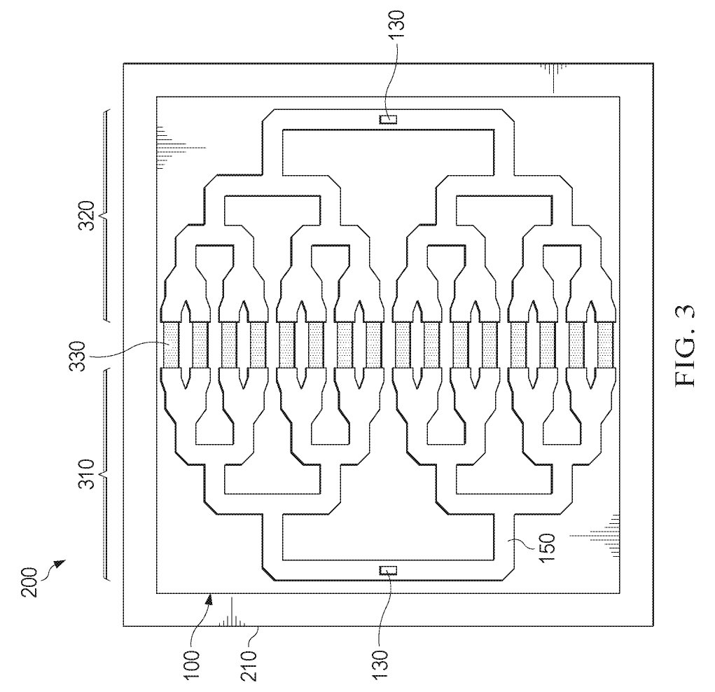

FIG. 3 is a top view of an example planar SSPA device 200, in accordance with at least one embodiment of the present disclosure. The planar SSPA device 200 includes a planar SSPA 100 bonded to a heat sink or heat spreader 210. The planar SSPA 100 includes substrate-integrated waveguides (SIWs) 150, which may for example be air gaps formed into a glass substrate and surrounded by metal-filled vias, as will be appreciated by a person of ordinary skill in the art. In the example shown in FIG. 3, the SIWs 150 form a 16-way splitter 310 for splitting incoming RF energy and a 16-way combiner 320 for combining RF energy into a single output. In between the splitter 310 and the combiner 320 sit 16 power amplifiers 330, which may for example be MMICs. The SIWs 150 also connect to the backside slots 130, thus allowing RF energy to be directed into and out of the waveguides machined into the heat sink 210.

The planar splitter 310 and combiner 320 are realized using substrate integrated waveguide (SIW) technology. While not shown, one or more redistribution layers (RDLs) could be on the top side of the substrate for DC routing or other purposes, and other components and circuitry (not shown) may be provided on the top surface as needed to drive the PAs 330. In this example, 16 PAs 330 are combined. These PAs 330 could be bare-die MMICs, packaged MMICs, or other solid-state amplifiers, with the SIW to PA transition being customized based on the amplifiers being used.

It is understood that the splitter 310 and combiner 320 may be configured for a different number of power amplifiers 330 than shown, whether larger or smaller than 16.

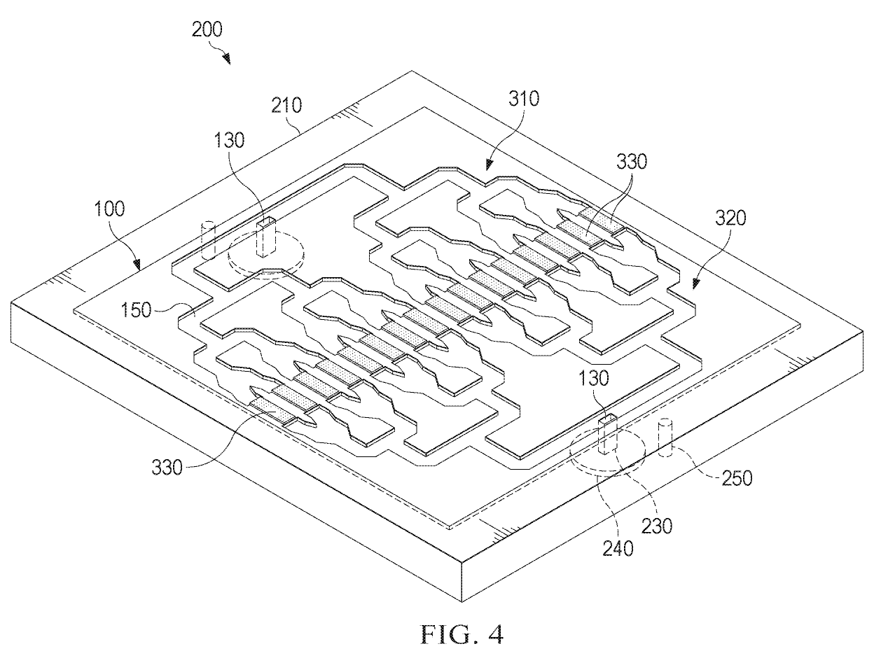

FIG. 4 is a top side perspective view of an example planar SSPA device 200, in accordance with at least one embodiment of the present disclosure. Visible are the planar SSPA 100, heat sink or heat spreader 210, SIWs 150, splitter 310, combiner 320, power amplifiers (PAs) 330, and backside slots 130. Also visible on the bottom of the heat sink 210 are a socket 240 for receiving a standard flanged external waveguide component such as a WR-XX (e.g., WR-10) flanged component. The socket 240 includes a bolt hole 250.

As can be seen in FIG. 4, because the socket 240 is located on the bottom of the heat sink 210, the topside area of the planar SSPA 100 does not need to accommodate the socket 240. This allows either for the size of the planar SSPA 100 to be smaller than a socketed SSPA, or for more PAs 330 to fit onto a planar SSPA 100 of a given size.

The input and output of the planar SSPA 100 is realized as a backside slot 130 in the SIW splitter 310 and combiner 320. This slot in the SIW is designed to launch into a standard rectangular waveguide based on the frequency of operation. The standard rectangular waveguide that mates to the SIW slot coupled launch is machined directly into the heat sink. This allows the flanged external waveguide component to mate on the backside of the heat sink rather than into the top side of the substrate. Eliminating the need for the substrate to grow to accept the flanged component. Without this innovation, depending on the amount of combining, over half of the substrate might be necessary simply for accepting the flanged input and output. Integrating the sockets instead into the backside of the heat sink allows a much smaller, more elegant solution than bringing it into the topside of the SIW/SSPA substrate. This reduces cost and even becomes an enabling concept in the case the maximum circuit size is approached for the planar substrate.

In some embodiments, the glass substrate of the planar SSPA 100 may include cavities positioned such that the PAs 330 are in direct contact with the heat sink.

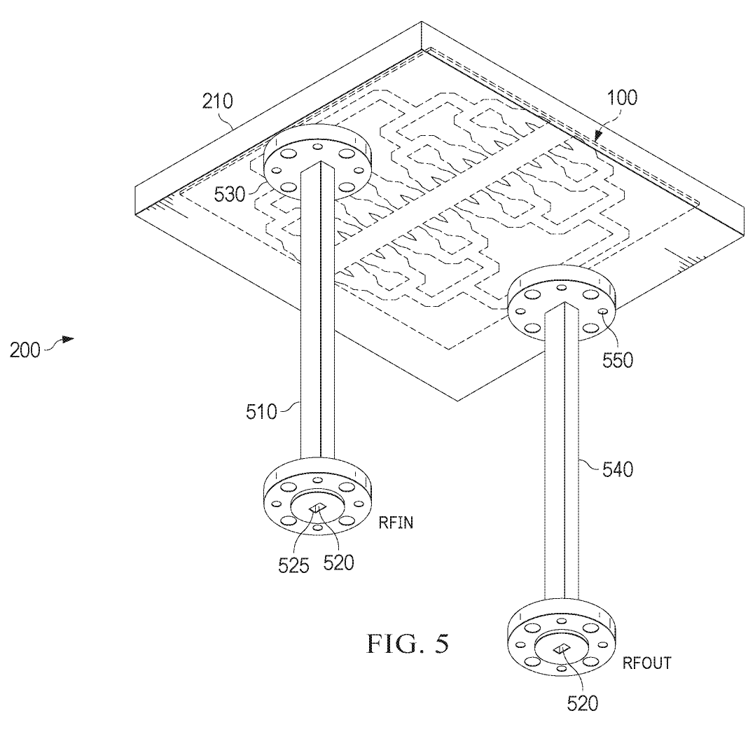

FIG. 5 is a bottom side perspective view of an example planar SSPA device 200, in accordance with at least one embodiment of the present disclosure. Visible are the planar SSPA 100 and heat sink 210. Also visible is an input external waveguide component 510, which is bolted to one of the sockets 240 of FIGS. 2 and 4. The input external waveguide component 510 includes a hollow (e.g., air-filled) waveguide 520 defined by a surrounding metal tube 525, which connects (via the backside slot 130 – see FIG. 3) to the splitter 310, such that the RF energy carried by the waveguide 520 can be split into multiple amplification pathways. The input external waveguide component 510 also includes two end flanges 530, each having bolt holes 550 for bolting the flange 530 to the socket 240 via the bolt holes 250 (see FIG. 2).

Also visible is an output external waveguide component 540, which is bolted to the other socket 240. The external waveguide component 540 includes a waveguide 520 that connects (via the other backside slot 130) to the combiner, such that RF energy exiting the power amplifiers can be recombined and directed outside of the planar SSPA device 200.

The example of FIG. 5 shows waveguide straight sections interfacing with the backside of the heat sink, functioning as the RFIN and RFOUT. These could be any standard waveguide component (e.g. E-plane bend, H-plane bend, etc.) The architecture is quite flexible from that standpoint. In the example shown in FIG. 5, this is implemented at W-Band and the size (ignoring the flanged components) is approximately 75mm x 75mm x 7mm, which is quite a compact unit. As a comparison, in the existing art, a puck combines 16 PAs in a form factor of 2.048” x 2.225” x .750”, which is 3.4 cubic inches. The solution here combines 16 PAs in a form factor of 2.4 cubic inches. This is likely able to be integrated into the skin of an aircraft or some other challenging platform.

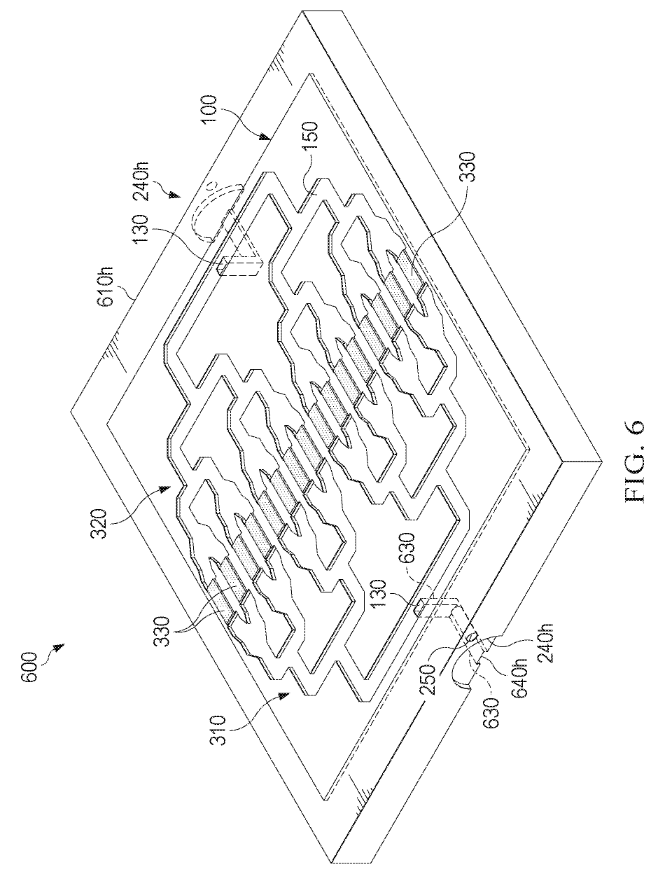

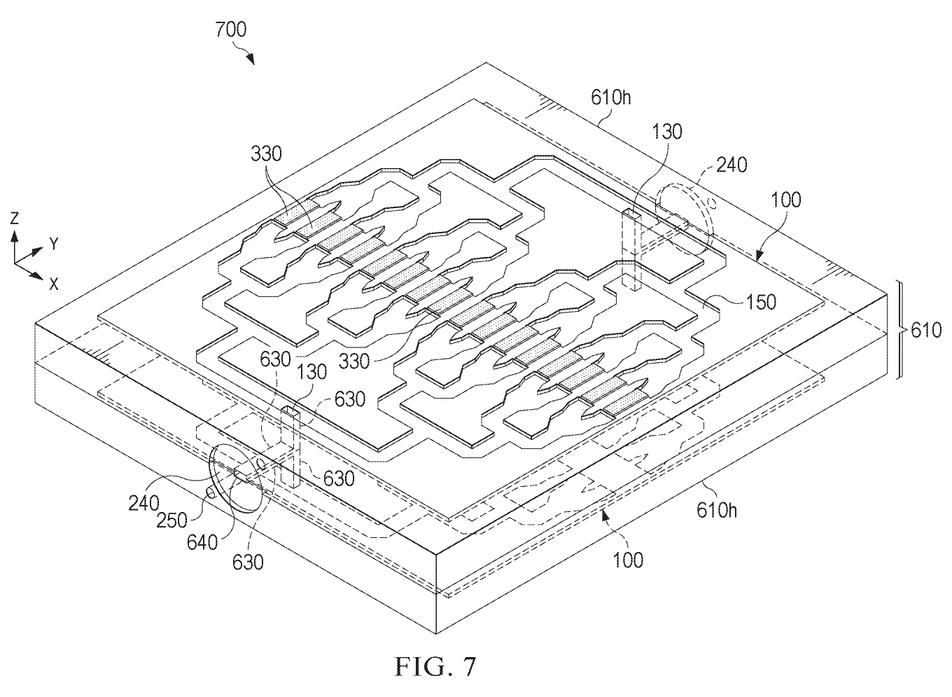

The concept can be extended elegantly to combine two planar SSPAs by machining a half T-splitter / combiner into the heat sink and then sandwiching the two together, as shown below in FIGS. 6 and 7.

FIG. 6 is a top side perspective view of an example planar SSPA device 600, in accordance with at least one embodiment of the present disclosure. Visible are the planar SSPA 100 and heat sink half 610h. The planar SSPA 100 includes substrate integrated waveguides (SIWs) 150 that form a splitter 310 and combiner 320. Also visible are the PAs 330 and backside slots 130.

In the example shown in FIG. 6, the heat sink half 610h includes an L-shaped waveguide 630 connecting the backside slot 130 to a half-socket 240h, which includes half of a waveguide entry aperture 640h and a bolt hole 250. A similar waveguide 630, half-socket 240h, half-aperture 640h, and bolt hole 250 may be found on the opposite (hidden) side of the heat sink half 610h.

The heat sink half 610h is configured such that it can be added to a second (e.g., flipped-over) heat sink half 610h to form a completed heat sink 610, as shown for example in FIG. 7.

FIG. 7 is a top side perspective view of an example planar SSPA device 700, in accordance with at least one embodiment of the present disclosure. Visible are two planar SSPAs 100 on opposite faces of a heat sink 610 formed from two heat sink halves 610h. The planar SSPAs 100 each include substrate integrated waveguides (SIWs) 150 that form a splitter 310 and combiner 320. Also visible are the PAs 330 and backside slots 130.

In the example shown in FIG. 7, each heat sink half 610h includes an L-shaped waveguide 630 connecting the backside slot 130 to a socket 240, which includes a waveguide entry aperture 640 and two bolt holes 250. A similar waveguide 630, socket 240, half-aperture 640, and bolt holes 250 may be found on the opposite (hidden) side of the heat sink 610.

In this configuration, the heat sink 610 is able to support two planar SIW/SSPA substrates, and thus two splitters, two sets of PAs, and two combiners, attached to a single input socket and output socket. Thus, the configuration of FIG. 7 has twice the amplification power of the configurations shown in FIGS. 3-6, while retaining the same area in the X-Y plane. In addition, the configuration shown in FIG. 7 allows the external waveguides 510 and 540 (see FIG. 5) to be connected in the X-Y plane, thus dramatically reducing the Z-height of the device 700 as compared to the device 200 of FIG. 5.

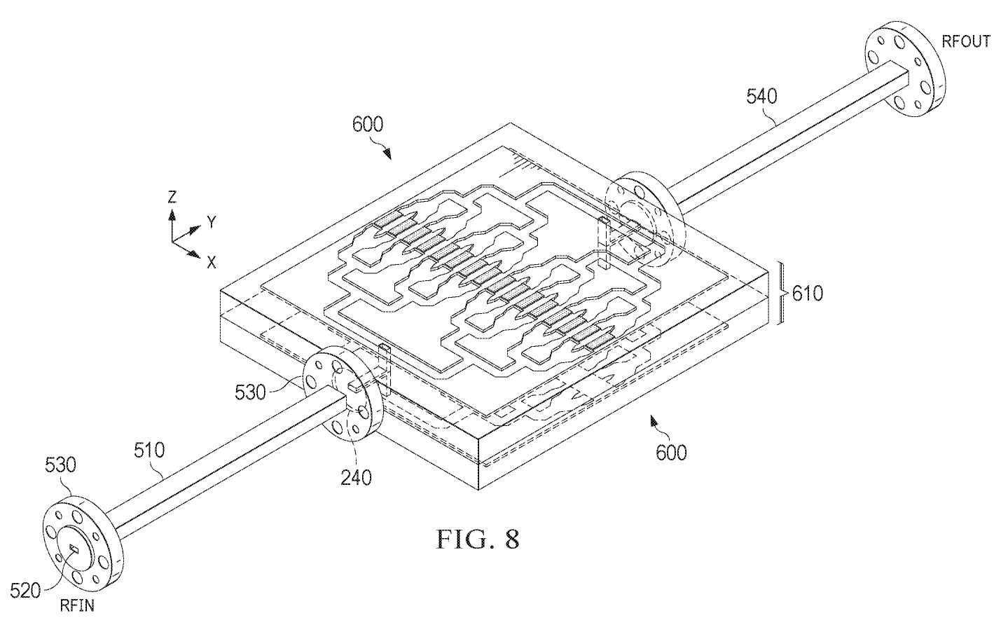

FIG. 8 is a top side perspective view of the planar SSPA device 600 of FIG. 6, with the RF input waveguide 510 and RF output waveguide 540 attached, in accordance with at least one embodiment of the present disclosure. The flange 530 of the waveguide 510 is bolted to the socket 240 of the heat sink 610. In this W-band example, the size may for example be ~75mm x 75mm x 14mm – twice the volume of the device 500 shown in FIG. 5, but with also twice the amplification power. This configuration, being small in the Z dimension, may be particularly suited to being integrated into the skin of an aircraft, or other substantially two-dimensional applications.

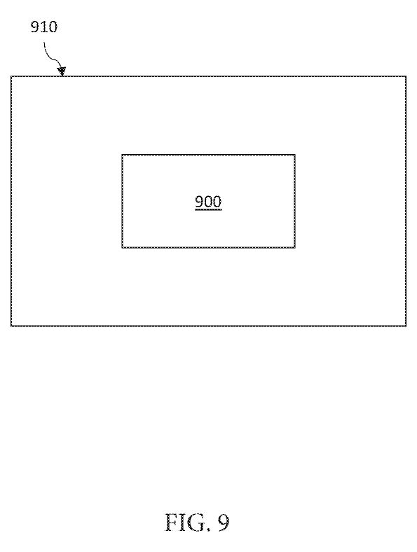

FIG. 9 is a schematic, diagrammatic view of an electronic device or a wireless device 910 comprising a novel planar SSPA device 900, in accordance with at least one embodiment of the present disclosure. In some implementations, the electronic device or wireless device 910 may include, for example, but not limited to, a computer, a cellular device, a satellite communication device, a wi-fi device, a radar, a global position system device, or any wireless device. In one or more embodiments, the novel planar SSPA device 900 may include one or more planar SIW/SSPA substrates mounted to a thermally conductive heat sink, such as SSPA device 200 of FIG. 2, SSPA device 600 of FIG. 6, SSPA device 700 of FIG. 7, or other planar SSPA device comprising a planar SSPA substrate mounted to a thermally conductive heat sink, with external waveguide interfaces integrated into the back/bottom or sides of the heat sink rather than into the top surface of the substrate. The novel planar SSPA device 900 may implement any RF component used in wireless applications, as an example, such as one or more RF power amplifiers or in a radar or radar systems; and the novel planar SSPA device 900 may be coupled to other circuitry for implementing a wireless application.

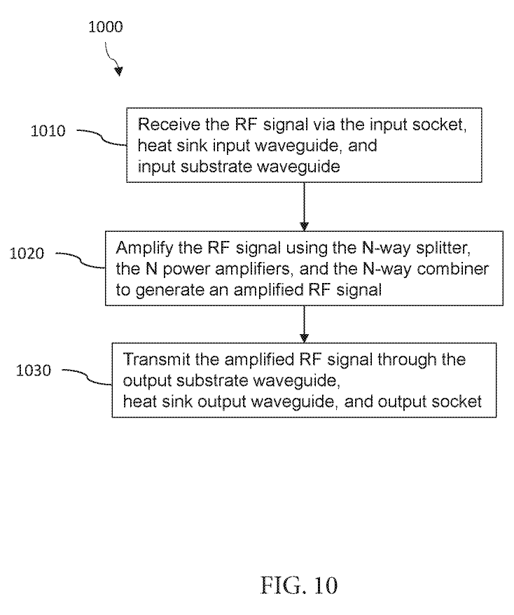

FIG. 10 is a schematic, diagrammatic representation, in flow diagram form, of an example signal amplification method 1000, in accordance with at least one embodiment of the present disclosure.

In step 1010, the method 1000 includes receiving the RF signal via the input socket, heat sink input waveguide, and input substrate waveguide. Execution the proceeds to step 1020.

In step 1020, the method 1000 includes amplifying the RF signal using the N-way splitter, the N power amplifiers, and the N-way combiner to generate an amplified RF signal. Execution then proceeds to step 1030.

In step 1030, the method 1000 includes transmitting the amplified RF signal through the output substrate waveguide, heat sink output waveguide, and output socket.

As will be readily appreciated by those having ordinary skill in the art after becoming familiar with the teachings herein, the novel planar SSPA device fills a long-standing need in the art, by using through-substrate vias or backslide slots, along with waveguides machined into the heat sink, to move the waveguide interface sockets from the substrate to the sides or back of the heat sink, thus allowing for more compact and/or more powerful devices.

A number of variations are possible on the examples and embodiments described above. For example, the substrate may be made of other materials than glass, the heat sink(s) may be made of other materials than metal, and the waveguides may be filled with other materials than air, while still performing the functions described herein. External waveguides may be of any size, dimension, and composition capable of performing the functions described herein. The technology described herein may be applied to other RF frequency bands than microwaves.

Accordingly, the logical operations making up the embodiments of the technology described herein are referred to variously as operations, steps, objects, elements, components, or modules. Furthermore, it should be understood that these may occur, be performed or arranged, in any order, unless explicitly claimed otherwise or a specific order is inherently necessitated by the claim language.

All directional references e.g., upper, lower, inner, outer, upward, downward, left, right, lateral, front, back, top, bottom, above, below, vertical, horizontal, clockwise, counterclockwise, proximal, and distal are only used for identification purposes to aid the reader’s understanding of the claimed subject matter, and do not create limitations, particularly as to the position, orientation, or use of the SSPA. Connection references, e.g., attached, coupled, connected, joined, or “in communication with” are to be construed broadly and may include intermediate members between a collection of elements and relative movement between elements unless otherwise indicated. As such, connection references do not necessarily imply that two elements are directly connected and in fixed relation to each other. The term “or” shall be interpreted to mean “and/or” rather than “exclusive or.” The word “comprising” does not exclude other elements or steps, and the indefinite article “a” or “an” does not exclude a plurality. Unless otherwise noted in the claims, stated values shall be interpreted as illustrative only and shall not be taken to be limiting.

The above specification, examples and data provide a complete description of the structure and use of exemplary embodiments of the SSPA as defined in the claims. Although various embodiments of the claimed subject matter have been described above with a certain degree of particularity, or with reference to one or more individual embodiments, those skilled in the art could make numerous alterations to the disclosed embodiments without departing from the spirit or scope of the claimed subject matter.

Still other embodiments are contemplated. It is intended that all matter contained in the above description and shown in the accompanying drawings shall be interpreted as illustrative only of particular embodiments and not limiting. Changes in detail or structure may be made without departing from the basic elements of the subject matter as defined in the following claims.

What is claimed is:

1. A device for amplifying radio frequency (RF) signals, the device comprising:
a planar dielectric substrate comprising:
a metallized top side;
a metallized bottom side;
a first hollow conductive slot forming an input substrate waveguide between the metallized top side and the metallized bottom side;
a first substrate-integrated waveguide (SIW) forming an N-way splitter located after the first conductive slot;
N power amplifiers located after the splitter;
a second SIW located after the N power amplifiers and forming an N-way combiner; and
a second hollow conductive slot located after the N-way combiner and forming an output substrate waveguide between the metallized top side and the metallized bottom side;
a heat sink comprising:
an input socket;
a heat sink input waveguide aligned with the input socket and the input substrate waveguide;
an output socket; and
a heat sink output waveguide aligned with the output socket and the output substrate waveguide.

2. The device of claim 1, further comprising:
an input external waveguide affixed to the input socket and aligned with the heat sink input waveguide; and
an output external waveguide affixed to the output socket and aligned with the heat sink output waveguide.

3. The device of claim 2, wherein the input socket or the output socket is located on a bottom face of the heat sink, such that the input external waveguide or the output external waveguide extends in a direction perpendicular to the planar dielectric substrate.

4. The device of claim 2, wherein the input socket or the output socket is located on a side face of the heat sink, such that the input external waveguide or the output external waveguide extends in a direction parallel to the planar dielectric substrate.

5. The device of claim 1, wherein the planar dielectric substrate comprises glass.

6. The device of claim 1, wherein at least one of the heat sink input waveguide, the input substrate waveguide, the first SIW, the second SIW, the output substrate waveguide, or the heat sink output waveguide comprises air.

7. The device of claim 1, wherein the N power amplifiers comprise N microwave monolithic integrated circuits (MMICs), and wherein the planar dielectric substrate includes cavities such that the MMICs are in direct contact with the heat sink.

8. A method for amplifying a radio frequency (RF) signal, the method comprising:
providing a planar dielectric substrate comprising a metallized top side and a metallized bottom side;
with a first hollow conductive slot, forming an input substrate waveguide between the metallized top side and the metallized bottom side;
with a first substrate-integrated waveguide (SIW), forming an N-way splitter located after the first conductive slot;
providing N power amplifiers located after the splitter;
with a second SIW located after the N power amplifiers, forming an N-way combiner;
with a second hollow conductive slot located after the N-way combiner, forming an output substrate waveguide between the metallized top side and the metallized bottom side;
providing a heat sink comprising:
an input socket;
a heat sink input waveguide aligned with the input socket and the input substrate waveguide;
an output socket;
a heat sink output waveguide aligned with the output socket and the output substrate waveguide;
receiving the RF signal via the input socket, heat sink input waveguide, and the input substrate waveguide;
amplifying the RF signal using the N-way splitter, the N power amplifiers, and the N-way combiner to generate an amplified RF signal; and
transmitting the amplified RF signal through the output substrate waveguide, heat sink output waveguide, and output socket.

9. The method of claim 8, further comprising:
affixing an input external waveguide affixed to the input socket such that the input external waveguide is aligned with the heat sink input waveguide; and
affixing an output external waveguide affixed to the output socket such that the output external waveguide is aligned with the heat sink output waveguide.

10. The method of claim 9, wherein the input socket or the output socket is located on a bottom face of the heat sink, such that the input external waveguide or the output external waveguide extends in a direction perpendicular to the planar dielectric substrate.

11. The method of claim 9, wherein the input socket or the output socket is located on a side face of the heat sink, such that the input external waveguide or the output external waveguide extends in a direction parallel to the planar dielectric substrate.

12. The method of claim 8, wherein the planar dielectric substrate comprises glass.

13. The method of claim 8, wherein at least one of the heat sink input waveguide, the input substrate waveguide, the first SIW, the second SIW, the output substrate waveguide, or the heat sink output waveguide comprises air.

14. The method of claim 9, wherein the N power amplifiers comprise N microwave monolithic integrated circuits (MMICs) , and wherein the planar dielectric substrate includes cavities such that the MMICs are in direct contact with the heat sink.

15. A wireless device comprising:
an amplification device comprising:
a planar dielectric substrate comprising:
a metallized top side;
a metallized bottom side;
a first hollow conductive slot forming an input substrate waveguide between the metallized top side and the metallized bottom side;
a first substrate-integrated waveguide (SIW) forming an N-way splitter located after the first conductive slot;
N power amplifiers located after the splitter;
a second SIW located after the N power amplifiers and forming an N-way combiner; and
a second hollow conductive slot located after the N-way combiner and forming an output substrate waveguide between the metallized top side and the metallized bottom side;
a heat sink comprising:
an input socket;
a heat sink input waveguide aligned with the input socket and the input substrate waveguide;
an output socket; and
a heat sink output waveguide aligned with the output socket and the output substrate waveguide.

16. The wireless device of claim 15, further comprising:
an input external waveguide affixed to the input socket and aligned with the heat sink input waveguide; and
an output external waveguide affixed to the output socket and aligned with the heat sink output waveguide.

17. The wireless device of claim 16, wherein the input socket or the output socket is located on a bottom face of the heat sink, such that the input external waveguide or the output external waveguide extends in a direction perpendicular to the planar dielectric substrate.

18. The wireless device of claim 16, wherein the input socket or the output socket is located on a side face of the heat sink, such that the input external waveguide or the output external waveguide extends in a direction parallel to the planar dielectric substrate.

19. The wireless device of claim 15, wherein the planar dielectric substrate comprises glass.

20. The wireless device of claim 15, wherein at least one of the heat sink input waveguide, the input substrate waveguide, the first SIW, the second SIW, the output substrate waveguide, or the heat sink output waveguide comprises air.
